(19) United States
(12) Patent Application Publication
(10) Pub. No.: US 2011/0260723 A1
(43) Pub. Date: Oct. 27, 2011

(54) HALL DEVICE AND MAGNETIC SENSOR CIRCUIT

(75) Inventor: Dong Ok HAN, Suwon (KR)

(73) Assignee: Samsung Electro-Mechanics Co., Ltd., Suwon (KR)

(21) Appl. No.: 12/832,563

(22) Filed: Jul. 8, 2010

(30) Foreign Application Priority Data
Apr. 23, 2010 (KR) 1020100037936

(51) Int. Cl. G01R 33/06; H01C 1/012

(52) U.S. Cl. 324/251; 338/306

(57) ABSTRACT

A Hall device includes: a main plate, formed as a first metal plate, including first and second terminals that can be selectively connected to a power source terminal, third and fourth terminals that can be selectively connected to a ground, fifth and sixth terminals that can be connected to first and third terminals, respectively, a first resistor disposed between the first and second terminals, a second resistor disposed between the fifth and sixth terminals, a third resistor disposed between the third and fourth terminals, and a fourth resistor disposed between the second and fourth terminals, all of which being formed on the first metal plate; and a first auxiliary plate, formed as a second metal plate adjacent to the first metal plate of the main plate, including first and second auxiliary terminals that can be connected to the first and third terminals, and a fifth resistor disposed between the first and second auxiliary terminals, all of which being formed on the second metal plate.

### CROSS-REFERENCE TO RELATED APPLICATIONS

This application claims the priority of Korean Patent Application No. 10-2010-0037936 filed on Apr. 23, 2010, in the Korean Intellectual Property Office, the disclosure of which is incorporated herein by reference.

### BACKGROUND OF THE INVENTION

1. Field of the Invention

The present invention relates to a Hall device and a magnetic sensor circuit applicable to a mobile phone, a motor, or the like, and, more particularly, to a Hall device and a magnetic sensor circuit capable of reducing an occupied area and power consumption by canceling an offset by using an additional resistance plate.

2. Description of the Related Art

In general, a Hall device detects a magnetic field by using a Hall effect. The Hall effect is that when a magnetic field is applied to a certain conductor in which current flows, a force (i.e., Lorentz force) is generated in a certain, regular direction, to change a flow of current to make voltages at two detection ends different (referred to as a ‘Hall voltage’, hereinafter), and a Hall sensor can detect the magnetic field by using the Hall voltage.

In order for the Hall sensor to accurately detect the magnetic field, a zero voltage must be output without a magnetic field at an outer side. Thus, in order to better the characteristics of the Hall device, various forms, processes, doping density, or the like are adjusted to develop a specified Hall device.

In general, the Hall sensor, including a Hall device and its relevant circuits, can be implemented as an integrated circuit (IC) by using a general CMOS process, and the most significant core configuration of the Hall sensor IC is a Hall device (plate) that generates voltage by the Lorentz force.

The Hall device may be fabricated to have various forms as mentioned above. Preferably, the Hall device outputs a zero voltage when no magnetic field is applied thereto, and outputs a voltage of a certain size (or amplitude) generated by the Lorentz force when a magnetic field is applied thereto, and the voltage in this case is called a Hall voltage.

Meanwhile, it is preferred for the Hall device not to generate distortion such as an offset or temperature, but due to several factors such as a fabrication technique, a fabrication process, and the like, the Hall device occasionally outputs an offset having a certain voltage size, not a zero voltage. The generation of the offset in the Hall device degrades the sensitivity of the Hall sensor by the size of the offset.

Thus, a technique for reducing an offset through a plurality of Hall devices has been developed, but the use of the plurality of Hall devices causes problems in that the area occupied by the Hall devices increases, power consumption increases, and the fabrication cost thereof is increased.

### SUMMARY OF THE INVENTION

An aspect of the present invention provides a Hall device and a magnetic sensor circuit capable of reducing an occupied area and power consumption by canceling an offset by using an additional resistance plate.

According to an aspect of the present invention, there is provided a Hall device including: a main plate, formed as a first metal plate, including first and second terminals that can be selectively connected to a power source terminal, third and fourth terminals that can be selectively connected to a ground, fifth and sixth terminals that can be connected to first and third terminals, respectively, a first resistor disposed between the first and second terminals, a second resistor disposed between the fifth and sixth terminals, a third resistor disposed between the third and fourth terminals, and a fourth resistor disposed between the second and fourth terminals, all of which being formed on the first metal plate; and a first auxiliary plate, formed as a second metal plate adjacent to the first metal plate of the main plate, including first and second auxiliary terminals that can be connected to the first and third terminals, and a fifth resistor disposed between the first and second auxiliary terminals, all of which being formed on the second metal plate.

The fifth resistor may have the same resistance value as that of the second resistor.

According to another aspect of the present invention, there is provided a Hall device including: a main plate, formed as a first metal plate, including first and second terminals that can be selectively connected to a power source terminal, third and fourth terminals that can be selectively connected to a ground, fifth and sixth terminals that can be connected to first and third terminals, respectively, seventh and eighth terminals that can be connected to the second and fourth terminals, respectively, a first resistor disposed between the first and second terminals, a second resistor disposed between the fifth and sixth terminals, a third resistor disposed between the third and fourth terminals, and a fourth resistor disposed between the seventh and eighth terminals, all of which being formed on the first metal plate; a first auxiliary plate, formed as a second metal plate adjacent to the first metal plate of the main plate, including first and second auxiliary terminals that can be connected to the first and third terminals, and a fifth resistor disposed between the first and second auxiliary terminals, all of which being formed on the second metal plate; and a second auxiliary plate, formed as a third metal plate adjacent to the first metal plate of the main plate, including third and fourth auxiliary terminals that can be connected to the second and fourth terminals, and a sixth resistor disposed between the third and fourth auxiliary terminals, all of which being formed on the third metal plate.

The fifth resistor may have the same resistance value as that of the second resistor, and the sixth resistor may have the same resistance value as that of the fourth resistor.

According to another aspect of the present invention, there is provided a magnetic sensor circuit including: a Hall device including a main plate and a first auxiliary plate wherein the main plate, formed as a first metal plate, includes first and second terminals that can be selectively connected to a power source terminal, third and fourth terminals that can be selectively connected to a ground, fifth and sixth terminals that can be connected to first and third terminals, respectively, a first resistor disposed between the first and second terminals, a second resistor disposed between the fifth and sixth terminals, a third resistor disposed between the third and fourth terminals, and a fourth resistor disposed between the second and fourth terminals, all of which being formed on the first metal plate, and the first auxiliary plate, formed as a second metal plate adjacent to the first metal plate of the main plate, includes first and second auxiliary terminals that can be connected to the first and third terminals, and a fifth resistor disposed between the first and second auxiliary terminals, all of which being formed on the second metal plate; a switching circuit unit including a first switch that connects the first terminal to one of the fifth terminal and the first auxiliary terminal according to a pre-set first terminal switching signal, and a second switch that connects the third terminal to one of the sixth terminal and the second auxiliary terminal according to a pre-set second terminal switching signal; and a signal processing unit setting an offset voltage according to a first offset voltage between the second and third terminals selected when a pre-set power switching signal is a first clock and a second offset voltage between the first and fourth terminals selected when the power switching signal PSW is a second clock, in order to cancel an offset.

The fifth resistor may have the same resistance value as that of the second resistor.

The magnetic sensor circuit may further include: a switching controller generating the first and second terminal switching signals according to a pre-set selection and providing the generated first and second terminal switching signals to the first and second switches.

The first switch may be synchronized with the second switch according to the first and second switching signals in order to connect the first terminal to the fifth terminal when the third terminal is connected to the sixth terminal, and connect the first terminal to the first auxiliary terminal when the third terminal is connected to the second auxiliary terminal.

While the first and third terminals are being connected to the fifth and sixth terminals, respectively, by the first and second switches, the power switching signal (PSW) becomes a first clock, so the signal processing unit receives a first offset voltage between the second and third terminals, and while the first and third terminals are being connected to the first and second auxiliary terminals, respectively, by the first and second switches, the power switching signal (PSW) becomes a second clock, so the signal processing unit receives a second offset voltage between the first and fourth terminals.

According to another aspect of the present invention, there is provided a magnetic sensor circuit including: a Hall device including a main plate, a first auxiliary plate and a second auxiliary plate, wherein the main plate, formed as a first metal plate, includes first and second terminals that can be selectively connected to a power source terminal, third and fourth terminals that can be selectively connected to a ground, fifth and sixth terminals that can be connected to first and third terminals, respectively, seventh and eighth terminals that can be connected to the second and fourth terminals, respectively, a first resistor disposed between the first and second terminals, a second resistor disposed between the fifth and sixth terminals, a third resistor disposed between the third and fourth terminals, and a fourth resistor disposed between the seventh and eighth terminals, all of which being formed on the first metal plate, the first auxiliary plate, formed as a second metal plate adjacent to the first metal plate of the main plate, includes first and second auxiliary terminals that can be connected to the first and third terminals, and a fifth resistor disposed between the first and second auxiliary terminals, all of which being formed on the second metal plate, and the second auxiliary plate, formed as a third metal plate adjacent to the first metal plate of the main plate, includes third and fourth auxiliary terminals that can be connected to the second and fourth terminals, and a sixth resistor disposed between the third and fourth auxiliary terminals, all of which being formed on the third metal plate; a switching circuit unit including a first switch that connects the first terminal to one of the fifth terminal and the first auxiliary terminal according to a pre-set first terminal switching signal, a second switch that connects the third terminal to one of the sixth terminal and the second auxiliary terminal according to a pre-set second terminal switching signal, a third switch that connects the second terminal to one of the seventh terminal and the third auxiliary terminal according to a pre-set third terminal switching signal, and a fourth switch that connects the fourth terminal to one of the eighth terminal and the fourth auxiliary terminal according to a pre-set fourth terminal switching signal; and a signal processing unit setting an offset voltage according to a first offset voltage between the second and third terminals selected when a pre-set power switching signal is a first clock and a second offset voltage between the first and fourth terminals selected when the power switching signal PSW is a second clock, in order to cancel an offset.

The fifth resistor may have the same resistance value as that of the second resistor, and the sixth resistor may have the same resistance value as that of the fourth resistor.

The magnetic sensor circuit may further include: a switching controller generating the first, second, third, and fourth terminal switching signals according to a pre-set selection and providing the generated first, second, third, and fourth terminal switching signals to the first, second, third, and fourth switches, respectively.

The first switch may be synchronized with the second, third and fourth switches according to the first, second, third and fourth switching signals in order to connect the first terminal to the fifth terminal when the third terminal is connected to the sixth terminal, when the second terminal is connected to the seventh terminal, and the fourth terminal is connected to the eighth terminal, and connect the first terminal to the first auxiliary terminal when the third terminal is connected to the second auxiliary terminal, when the second terminal is connected to the third auxiliary terminal, and when the fourth terminal is connected to the fourth auxiliary terminal.

While the first, second, third, and fourth terminals are being connected to the fifth, seventh, sixth, and eighth terminals, respectively, by the first, second, third and fourth switches, the power switching signal (PSW) becomes a first clock, so the signal processing unit receives a first offset voltage between the second and third terminals, and while the first, second, third, and fourth terminals are being connected to the first, third, second, and fourth auxiliary terminals, respectively, by the first and second switches, the power switching signal (PSW) becomes a second clock, so the signal processing unit receives a second offset voltage between the first and fourth terminals.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 illustrates a first exemplary embodiment of a Hall device according to the present invention;

FIG. 2 illustrates a second exemplary embodiment of a Hall device according to the present invention;

FIG. 3 illustrates a first exemplary embodiment of a magnetic sensor circuit according to the present invention;

FIG. 4 illustrates a first usage embodiment of the magnetic sensor circuit of FIG. 3;

FIG. 5 illustrates a second usage embodiment of the magnetic sensor circuit of FIG. 3;

FIG. 6 illustrates a second exemplary embodiment of a magnetic sensor circuit according to the present invention;

FIG. 7 illustrates a first usage embodiment of the magnetic sensor circuit of FIG. 6; and

FIG. 8 illustrates a second usage embodiment of the magnetic sensor circuit of FIG. 6.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

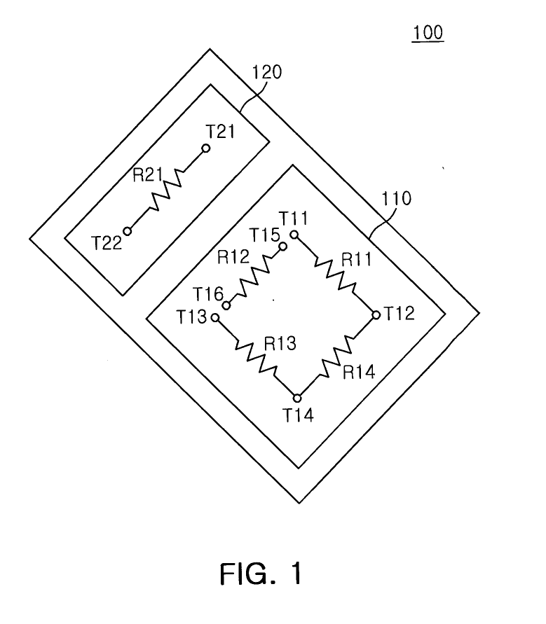

FIG. 1 illustrates a first exemplary embodiment of a Hall device according to the present invention.

With reference to FIG. 1, a first exemplary embodiment of a Hall device 100 according to the present invention may include a main plate 110 and a first auxiliary plate 120.

The main plate 110 is formed as a first metal plate. The main plate 110 may include first and second terminals T11 and T12 that can be selectively connected to a power source terminal Vdd, third and fourth terminals T13 and T14 that can be selectively connected to a ground, fifth and sixth terminals T15 and T16 that can be connected to the first and third terminals T11 and T13, respectively, a first resistor R11 disposed between the first and second terminals T11 and T12, a second resistor R12 disposed between the fifth and sixth terminals T15 and T16, a third resistor R13 disposed between the third and fourth terminals T13 and T14, and a fourth resistor R14 disposed between the second and fourth terminals T12 and T14, all of which are formed on the first metal plate.

The first auxiliary plate 120 is formed as a second metal plate adjacent to the first metal plate of the main plate. The first auxiliary plate 120 may include first and second auxiliary terminals T21 and T22 that can be connected to the first and third terminals T11 and T13, and a fifth resistor R21 disposed between the first and second auxiliary terminals T21 and T22, all of which are formed on the second metal plate.

The fifth resistor R21 may be switched together with the second resistor, and in this case, the fifth resistor R21 may have the same resistance value as that of the second resistor R12.

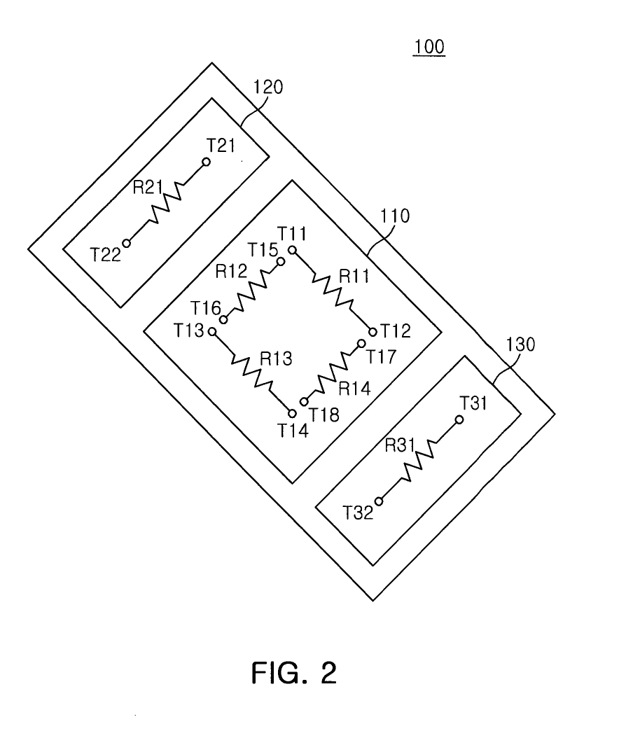

FIG. 2 illustrates a second exemplary embodiment of a Hall device according to the present invention.

With reference to FIG. 2, a second exemplary embodiment of the Hall device 100 according to the present invention may include a main plate 110, a first auxiliary plate 120, and a second auxiliary plate 130.

The main plate 110 is formed as a first metal plate. The main plate 110 may include first and second terminals T11 and T12 that can be selectively connected to a power source terminal Vdd, third and fourth terminals T13 and T14 that can be selectively connected to a ground, fifth to eighth terminals, a first resistor R11 disposed between the first and second terminals T11 and T12, a second resistor R12 disposed between the fifth and sixth terminals T15 and T16, a third resistor R13 disposed between the third and fourth terminals T13 and T14, and a fourth resistor R14 disposed between the seventh and eighth terminals T17 and T18, all of which are formed on the first metal plate.

The first auxiliary plate 120 is formed as a second metal plate adjacent to the first metal plate of the main plate 110. The first auxiliary plate 120 may include first and second auxiliary terminals T21 and T22 that can be connected to the first and third terminals T11 and T13, and a fifth resistor R21 disposed between the first and second auxiliary terminals T21 and T22, all of which are formed on the second metal plate, all of which are formed on the second metal plate.

The second auxiliary plate 130 is formed as a third metal plate adjacent to the first metal plate of the main plate 110. The second auxiliary plate 130 may include third and fourth auxiliary terminals T31 and T32 that can be connected to the second and fourth terminals T12 and T14, and a sixth resistor R31 disposed between the third and fourth auxiliary terminals T31 and T32, all of which are formed on the third metal plate.

The fifth resistor R21 may be switched together with the second resistor R12, and in this case, the fifth resistor R21 may have the same resistance value as that of the second resistor R12, and the sixth resistor R31 may be switched together with the fourth resistor R14, and in this case, the sixth resistor R31 may have the same resistance value as that of the fourth resistor R14.

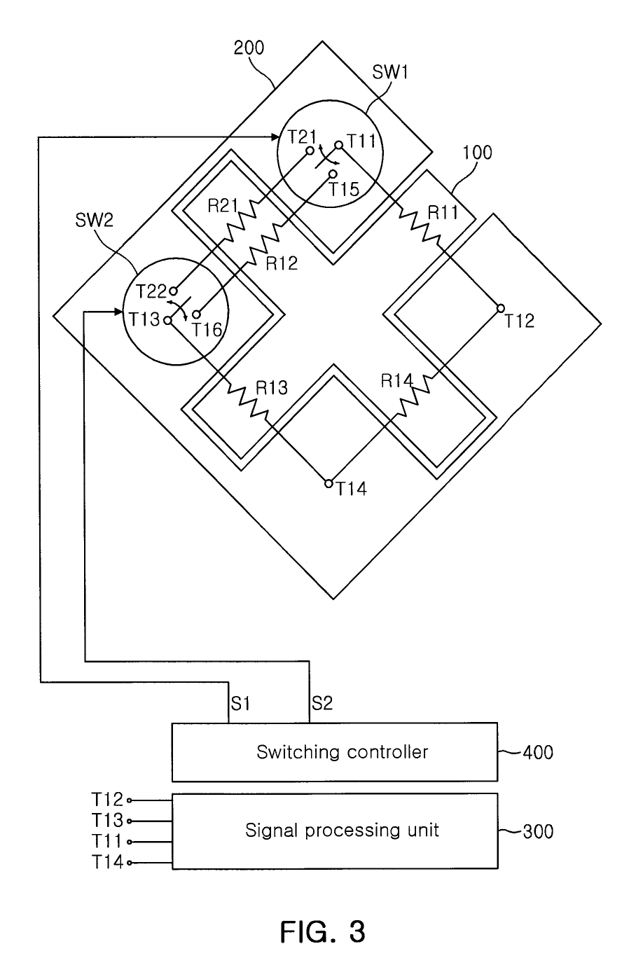

FIG. 3 illustrates a first exemplary embodiment of a magnetic sensor circuit according to the present invention.

With reference to FIG. 3, a first exemplary embodiment of a magnetic sensor circuit according to the present invention may include the Hall device 100, a switching circuit unit 200, and a signal processing unit 300.

The Hall device 100 may include the main plate 110 and the first auxiliary plate 120.

The main plate 110 is formed as a first metal plate. The main plate 110 may include first and second terminals T11 and T12 that can be selectively connected to a power source terminal Vdd, third and fourth terminals T13 and T14 that can be selectively connected to a ground, fifth and sixth terminals T15 and T16, a first resistor R11 disposed between the first and second terminals T11 and T12, a second resistor R12 disposed between the fifth and sixth terminals T15 and T16, a third resistor R13 disposed between the third and fourth terminals T13 and T14, and a fourth resistor R14 disposed between the second and fourth terminals T12 and T14, all of which are formed on the first metal plate.

The first auxiliary plate 120 is formed as a second metal plate adjacent to the first metal plate of the main plate. The first auxiliary plate 120 may include first and second auxiliary terminals T21 and T22 that can be connected to the first and third terminals T11 and T13, and a fifth resistor R21 disposed between the first and second auxiliary terminals T21 and T22, all of which are formed on the second metal plate.

The switching circuit unit 200 may include a first switch SW1 that connects the first terminal T11 to one of the fifth terminal T15 and the first auxiliary terminal T21 according to a pre-set first terminal switching signal, and a second switch SW2 that connects the third terminal T13 to one of the sixth terminal T16 and the second auxiliary terminal T22 according to a pre-set second terminal switching signal.

The signal processing unit 300 may set an offset voltage according to first offset voltage between the second and third terminals T12 and T13 selected when a pre-set power switching signal PSW is a first clock (CLK) and a second offset voltage between the first and fourth terminals selected when the power switching signal PSW is a second clock ( C̅L̅K̅), in order to cancel an offset.

The fifth resistor R21 may be switched together with the second resistor R12, and in this case, the fifth resistor R21 may have the same resistance value as that of the second resistor R12. The sixth resistor R31 may be switched together with the fourth resistor R14, and in this case, the sixth resistor R31 may have the same resistance value as that of the fourth resistor R14.

In the first exemplary embodiment of the magnetic sensor circuit of the present invention, the magnetic sensor circuit may further include a switching controller 400 that generates first and second terminal switching signals S1 and S2 according to a pre-set selection and provides the first and second terminal switching signals S1 and S2 to the first and second switches SW1 and SW2.

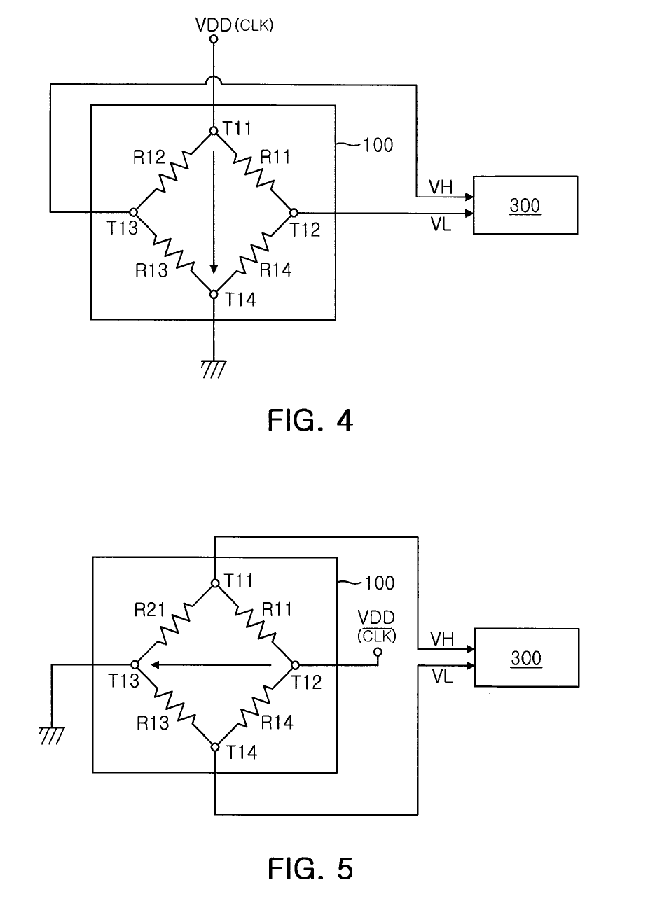

With reference to FIGS. 3 and 4, the first switch SW1 is synchronized with the second switch SW2 by the first and second switching signals S1 and S2 to connect the first terminal T11 to the fifth terminal T15 when the third terminal T13 is connected to the sixth terminal T16.

In this case, while the first and third terminals T11 and T13 are connected to the fifth and sixth terminals T15 and T16, respectively, by the first and second switches SW1 and SW2, the power switching signal PSW becomes the first clock CLK, so the signal processing unit 300 can receive a first offset voltage Voff1 between the second and third terminals T12 and T13.

Differently, with reference to FIGS. 3 and 5, the first switch SW1 is synchronized with the second switch SW2 by the first and second switching signals S1 and S2 to connect the first terminal T11 to the first auxiliary terminal T21 when the third terminal T13 is connected to the second auxiliary terminal T22.

In this case, while the first and third terminals T11 and T13 are connected to the first and second auxiliary terminals T21 and T22, respectively, by the first and second switches SW1 and SW2, the power switching signal PSW becomes the second clock ( C̅L̅K̅), so the signal processing unit 300 can receive a second offset voltage Voff2 between the first and fourth terminals T11 and T14.

FIG. 4 illustrates a first usage embodiment of the magnetic sensor circuit of FIG. 3 when the power switching signal PSW is the first clock (CLK), and FIG. 5 illustrates a second usage embodiment of the magnetic sensor circuit of FIG. 3 when the power switching signal PSW is the second clock ( C̅L̅K̅).

The circuit diagram illustrated in FIG. 4 is an equivalent circuit diagram of the Hall device 100 according to an exemplary embodiment of the present invention in the case in which the first terminal T11 is connected to the fifth terminal T15 by the first switch SW1 and the third terminal T13 is connected to the sixth terminal T16 by the second switch SW2.

In this case, when a current (Iin) flowing across the magnetic sensor circuit according to an exemplary embodiment of the present invention is uniform, the first offset voltage Voff1 is determined as a difference voltage between a voltage VH of the third terminal T13 and a voltage VL of the second terminal T12, which can be represented by Equation 1 shown below, and in this case, the total resistance is represented by Equation 2 shown below:

$$\begin{matrix}Voff 1 = VH - VL = ( \frac{R 13}{R 12 + R 13} - \frac{R 14}{R 14 + R 11} ) Vin , Vin - Iin \cdot Rtotal when C L K & [ Equation 1 ] \\ Rtotal = ( R 12 + R 13 ) // ( R 14 + R 11 ) = ( \frac{( R 12 + R 13 ) \cdot ( R 14 + R 11 )}{R 11 + R 12 + R 13 + R 14} ) & [ Equation 2 ]\end{matrix}$$

The circuit diagram illustrated in FIG. 5 is an equivalent circuit diagram of the Hall device 100 according to an exemplary embodiment of the present invention in the case in which the first terminal T11 selects the first auxiliary terminal T21 by the first switch SW1 and the third terminal T13 is connected to the second auxiliary terminal T22 by the second switch SW2.

In this case, when the current (Iin) flowing across the magnetic sensor circuit according to an exemplary embodiment of the present invention is uniform, the second offset voltage Voff2 is a difference voltage between a voltage VH of the first terminal T11 and a voltage VL of the fourth terminal T14, which can be represented by Equation 3 shown below, and in this case, the total resistance ( R̅t̅o̅t̅a̅l̅) is represented by Equation 4 shown below:

$$\begin{matrix}Voff 2 = VH - VL = ( \frac{R 21}{R 21 + R 11} - \frac{R 13}{R 13 + R 14} ) Vin , Vin = \overline{Iin} \cdot \overline{Rtotal} when \overline{C L K} & [ Equation 3 ] \\ \overline{Rtatal} = ( R 21 + R 11 ) // ( R 13 + R 14 ) = ( \frac{( R 21 + R 11 ) \cdot ( R 13 + R 14 )}{R 21 + R 13 + R 14 + R 11} ) & [ Equation 4 ]\end{matrix}$$

Equation 1 and Equation 2 can be represented by Equation 5 and Equation 6 shown below by using Equation 2 to Equation 4.

$$\begin{matrix}\begin{matrix}Voff 1 = ( \frac{R 13}{R 12 + R 13} - \frac{R 14}{R 14 + R 11} ) \cdot IinRtotal \\ = ( \frac{R 13 ( R 14 + R 11 ) - R 14 ( R 12 + R 13 )}{R 11 + R 12 + R 13 + R 14} ) \cdot Iin\end{matrix} & [ Equation 5 ] \\ \begin{matrix}Voff 2 = ( \frac{R 21}{R 21 + R 11} - \frac{R 13}{R 13 + R 14} ) \cdot IinR \overline{total} \\ = ( \frac{R 21 ( R 13 + R 14 ) - R 13 ( R 21 + R 11 )}{R 21 + R 13 + R 14 + R 11} ) \cdot Iin\end{matrix} & [ Equation 6 ]\end{matrix}$$

The offset voltage Voff in the magnetic sensor circuit according to an exemplary embodiment of the present invention may be represented by Equation 7 shown below by using Equation 5 and Equation 6.

$$\begin{matrix}Voff = Voff 1 + V off 2 \\ = ( \begin{matrix}\frac{( R 13 R 14 + R 13 R 11 ) - ( R 12 R 14 - R 1 R 14 )}{R 11 + R 12 + R 13 + R 14} + \\ \frac{( R 21 R 13 + R 21 R 14 ) - ( R 21 R 13 - R 13 R 11 )}{R 21 + R 13 + R 14 + R 11}\end{matrix} ) \cdot Vin\end{matrix} \qquad [ Equation 7 ]$$

When R13+R14+R11 in Equation 7 is A, Equation 7 may be represented by Equation 8 shown below:

$$\begin{matrix}Voff = ( \frac{R 13 R 11 - R 12 R 14}{R 12 + A} + \frac{R 21 R 14 - R 13 R 11}{R 21 + A} ) \cdot Iin \\ = ( \frac{\begin{matrix}( R 21 + A ) ( R 13 R 11 - R 12 R 14 ) + \\ ( R 12 + A ) ( R 21 R 14 - R 13 R 11 )\end{matrix}}{( R 12 + A ) ( R 21 + A )} ) \cdot Iin \\ = \frac{( R 21 - R 12 ) ( R 13 R 11 + AR 14 )}{( R 12 + A ) ( R 21 + A )} \\ = 0 ( ∵ R 21 = R 12 )\end{matrix} \qquad [ Equation 8 ]$$

In Equation 8, if the second resistor R12 and the fifth resistor R21 are the same, the offset voltage Voff can be 0. Namely, if the fifth resistor R21 is fabricated to be the same as the second resistor R12, the offset voltage Voff can become 0.

This method is advantageous in that the offset generated between the areas and elements can be minimized, compared with the related art employing an orthogonal modulation scheme with one Hall device or the related art canceling an offset by using two or more Hall devices.

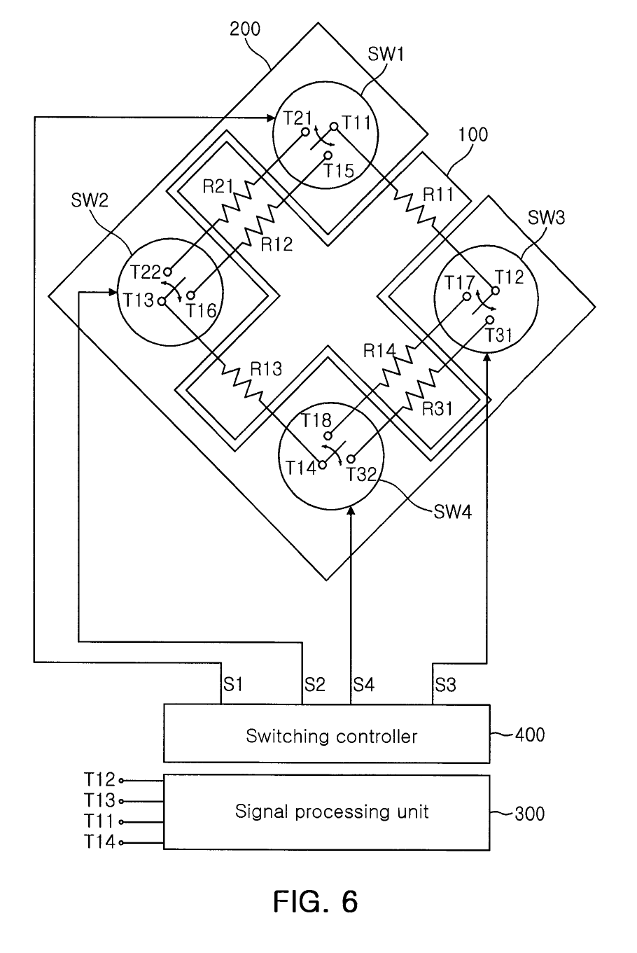

FIG. 6 illustrates a second exemplary embodiment of a magnetic sensor circuit according to the present invention.

With reference to FIG. 6, the second exemplary embodiment of a magnetic sensor circuit may include the Hall device 100, the switching circuit unit 200, and the signal processing unit 300.

The Hall device 100 may include the main plate 110, the first auxiliary plate 120, and the second auxiliary plate 130.

The main plate 110 is formed as a first metal plate. The main plate 110 may include first and second terminals T11 and T12 that can be selectively connected to a power source terminal Vdd, third and fourth terminals T13 and T14 that can be selectively connected to a ground, fifth to eighth terminals, a first resistor R11 disposed between the first and second terminals T11 and T12, a second resistor R12 disposed between the fifth and sixth terminals T15 and T16, a third resistor R13 disposed between the third and fourth terminals T13 and T14, and a fourth resistor R14 disposed between the seventh and eighth terminals T17 and T18, all of which are formed on the first metal plate.

The first auxiliary plate 120 is formed as a second metal plate adjacent to the first metal plate of the main plate 110. The first auxiliary plate 120 may include first and second auxiliary terminals T21 and T22 that can be connected to the first and third terminals T11 and T13, and a fifth resistor R21 disposed between the first and second auxiliary terminals T21 and T22, all of which are formed on the second metal plate.

The second auxiliary plate 130 is formed as a third metal plate adjacent to the first metal plate of the main plate 110. The second auxiliary plate 130 may include third and fourth auxiliary terminals T31 and T32 that can be connected to the second and fourth terminals T12 and T14, and a sixth resistor R31 disposed between the third and fourth auxiliary terminals T31 and T32, all of which are formed on the third metal plate.

The switching circuit unit 200 may include a first switch SW1 that connects the first terminal T11 to one of the fifth terminal T15 and the first auxiliary terminal T21 according to a pre-set first terminal switching signal, a second switch SW2 that connects the third terminal T13 to one of the sixth terminal T16 and the second auxiliary terminal T22 according to a pre-set second terminal switching signal, a third switch SW3 that connects the second terminal T12 to one of the seventh terminal T17 and the third auxiliary terminal T31 according to a pre-set third terminal switching signal, a fourth switch SW4 that connects the fourth terminal T14 to one of the eighth terminal T18 and the fourth auxiliary terminal T32 according to a pre-set fourth terminal switching signal.

The signal processing unit 300 may set an offset voltage according to first offset voltage between the second and third terminals T12 and T13 selected when a pre-set power switching signal PSW is a first clock (CLK) and a second offset voltage between the first and fourth terminals selected when the power switching signal PSW is a second clock ( C̅L̅K̅), in order to cancel an offset.

The fifth resistor R21 may have the same resistance value as that of the second resistor R12, and the sixth resistor R31 may have the same resistance value as that of the fourth resistor R14.

In the second exemplary embodiment of the magnetic sensor circuit of the present invention, the magnetic sensor circuit may further include a switching controller 400 that generates first to fourth terminal switching signals S1, S2, S3, and S4 according to a pre-set selection and provides the first to fourth terminal switching signals S1, S2, S3, and S4 to the first to fourth switches SW1, SW2, SW3, and SW4.

The first switch SW1 is synchronized with the second, third, and fourth switches SW2, SW3 and SW4 by the first, second, third, and fourth switching signals S1, S2, S3, and S4 in order to connect the first terminal T11 to the fifth terminal T15 when the third terminal T13 is connected to the sixth terminal T16, when the second terminal T12 is connected to the seventh terminal T17, and when the fourth terminal T14 is connected to the eighth terminal T18, and connect the first terminal T11 to the first auxiliary terminal T21 when the third terminal is connected to the second auxiliary terminal T22, when the second terminal is connected to the third auxiliary terminal T31, and when the fourth terminal T14 is connected to the fourth auxiliary terminal T32.

In this case, while the first, second, third, and fourth terminals T11, T12, T13, and T14 are being connected to the fifth, seventh, sixth, and eighth terminals T15, T17, T16, and T18, respectively, by the first, second, third, and fourth switches SW1, SW2, SW3, and SW4, the power switching signal PSW becomes the first clock CLK, so the signal processing unit 300 can receive a first offset voltage Voff1 between the second and third terminals T12 and T13, and while the first, second, third, and fourth terminals T11, T12, T13, and T14 are being connected to the first, third, second, and fourth auxiliary terminals T21, T22, T31 and T32, respectively, by the first and second switches SW1 and SW2, the power switching signal PSW becomes the second clock ( C̅L̅K̅), so the signal processing unit 300 can receive a second offset voltage Voff2 between the first and fourth terminals T11 and T14.

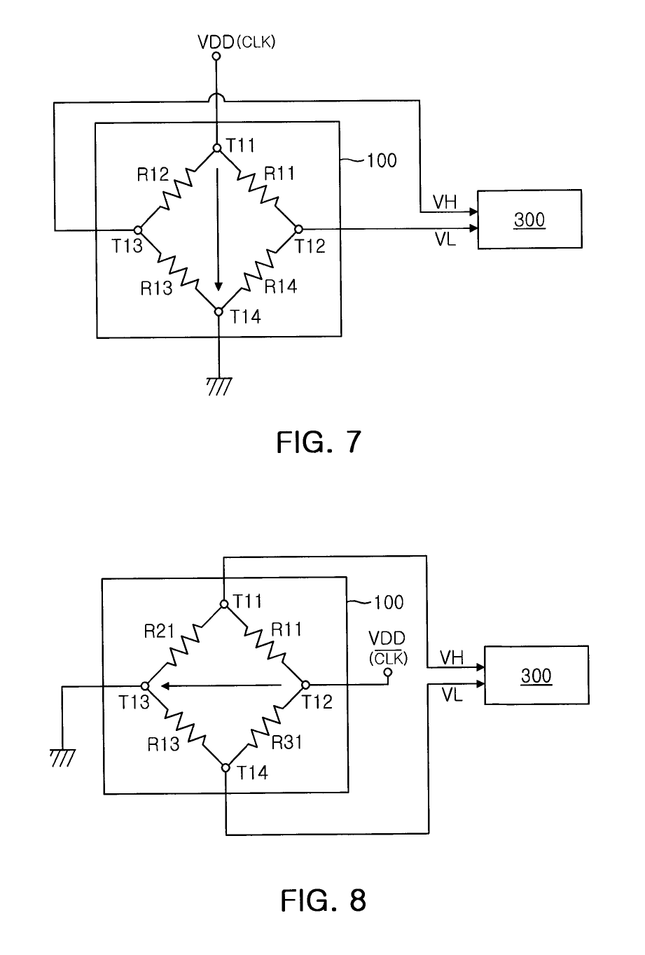

FIG. 7 illustrates a first usage embodiment of the magnetic sensor circuit of FIG. 6 when the power switching signal PSW is the first clock (CLK), and FIG. 8 illustrates a second usage embodiment of the magnetic sensor circuit of FIG. 7 when the power switching signal PSW is the second clock ( C̅L̅K̅).

The circuit diagram illustrated in FIG. 7 is an equivalent circuit diagram of the Hall device 100 according to an exemplary embodiment of the present invention in the case in which the first terminal T11 is connected to the fifth terminal T15 by the first switch SW1, the third terminal T13 is connected to the sixth terminal T16 by the second switch SW2, the second terminal T12 is connected to the seventh terminal T17 by the third switch SW3, and the fourth terminal T14 is connected to the eighth terminal T18 by the fourth switch SW4.

In this case, when a current (Iin) flowing across the magnetic sensor circuit according to an exemplary embodiment of the present invention is uniform, the first offset voltage Voff1 is a difference voltage between a voltage VH of the third terminal T13 and a voltage VL of the second terminal T12, which can be represented by Equation 9 shown below, and in this case, the total resistance is represented by Equation 10 shown below:

$$\begin{matrix}Voff 1 = VH - VL = ( \frac{R 13}{R 12 + R 13} - \frac{R 14}{R 14 + R 11} ) Vin , Vin - Iin \cdot Rtotal when C L K & [ Equation 9 ] \\ Rtotal = ( R 12 + R 13 ) // ( R 14 + R 11 ) = ( \frac{( R 12 + R 13 ) \cdot ( R 14 + R 11 )}{R 11 + R 12 + R 13 + R 14} ) & [ Equation 10 ]\end{matrix}$$

The circuit diagram illustrated in FIG. 8 is an equivalent circuit diagram of the Hall device 100 according to an exemplary embodiment of the present invention in the case in which the first auxiliary terminal T21 is selected by the first switch SW1, the second auxiliary terminal T22 is selected by the second switch SW2, the third auxiliary terminal T31 is selected by the third switch SW3, and the fourth auxiliary terminal T32 is selected by the fourth switch SW4

In this case, when the current (Iin) flowing across the magnetic sensor circuit according to an exemplary embodiment of the present invention is uniform, the second offset voltage Voff2 is a difference voltage between a voltage VH of the first terminal T11 and a voltage VL of the fourth terminal T14, which can be represented by Equation 11 shown below, and in this case, the total resistance ( R̅t̅o̅t̅a̅l̅) is represented by Equation 12 shown below:

$$\begin{matrix}Voff 2 = VH - VL = ( \frac{R 21}{R 21 + R 11} - \frac{R 13}{R 13 + R 14} ) Vin , Vin = \overline{Iin} \cdot \overline{Rtotal} when \overline{C L K} & [ Equation 11 ] \\ \overline{Rtatal} = ( R 21 + R 11 ) // ( R 13 + R 14 ) = ( \frac{( R 21 + R 11 ) \cdot ( R 13 + R 14 )}{R 21 + R 13 + R 14 + R 11} ) & [ Equation 12 ]\end{matrix}$$

Equation 9 and Equation 11 can be represented by Equation 13 and Equation 14 shown below by using Equation 10 to Equation 12.

$$\begin{matrix}\begin{matrix}Voff 1 = ( \frac{R 13}{R 12 + R 13} - \frac{R 14}{R 14 + R 11} ) \cdot IinRtotal \\ = ( \frac{R 13 ( R 14 + R 11 ) - R 14 ( R 12 + R 13 )}{R 11 + R 12 + R 13 + R 14} ) \cdot Iin\end{matrix} & [ Equation 13 ] \\ \begin{matrix}Voff 2 = ( \frac{R 21}{R 21 + R 11} - \frac{R 13}{R 13 + R 31} ) \cdot Iin \overline{Rtotal} \\ = ( \frac{R 21 ( R 13 + R 31 ) - R 13 ( R 21 + R 11 )}{R 21 + R 13 + R 31 + R 11} ) \cdot Iin\end{matrix} & [ Equation 14 ]\end{matrix}$$

The offset voltage (Voff) in the magnetic sensor circuit according to an exemplary embodiment of the present invention can be represented by Equation 15 shown below by using Equation 13 and Equation 14.

$$\begin{matrix}Voff = Voff 1 + Voff 2 \\ = ( \begin{matrix}\frac{\begin{matrix}( R 13 R 14 + R 13 R 11 ) - \\ ( R 12 R 14 - R 13 R 14 )\end{matrix}}{R 11 + R 12 + R 13 + R 14} + \\ \frac{\begin{matrix}( R 21 R 13 + R 21 R 31 ) - \\ ( R 21 R 13 - R 13 R 11 )\end{matrix}}{R 21 + R 12 + R 31 + R 14}\end{matrix} ) \cdot Vin\end{matrix} \qquad [ Equation 15 ]$$

When R13+R11 in Equation 15 is A, Equation 15 may be represented by Equation 16 shown below:

$$\begin{matrix}Voff = ( \frac{R 13 R 11 - R 12 R 14}{R 12 + R 14 + B} + \frac{R 21 R 31 - R 13 R 11}{R 21 + R 31 + B} ) \cdot Iin \\ = ( \frac{\begin{matrix}\begin{matrix}R 13 R 11 ( R 21 + R 31 + B ) - \\ R 12 R 14 ( R 21 + R 31 + B ) +\end{matrix} \\ \begin{matrix}R 21 + R 31 ( R 12 + R 14 + B ) - \\ R 13 R 11 ( R 12 + R 14 + B )\end{matrix}\end{matrix}}{( R 12 + R 14 + B ) ( R 21 + R 31 + B )} ) \cdot Iin \\ = ( \frac{\begin{matrix}\begin{matrix}( R 21 - R 12 ) ( R 13 R 11 + R 14 R 31 ) + \\ ( R 31 - R 14 ) R 13 R 11 +\end{matrix} \\ B ( R 21 R 31 - R 12 R 14 )\end{matrix}}{( R 12 + R 14 + B ) ( R 21 + R 31 + B )} ) \cdot Iin \\ = 0 ( ∵ R 21 = R 12 and R 31 = R 14 )\end{matrix} \qquad [ Equation 16 ]$$

In Equation 16, if the second resistor R12 and the fifth resistor R21 are the same and if the fourth resistor R14 and the sixth resistor R31 are the same, the offset voltage Voff can be 0. Namely, if the fifth resistor R21 and the sixth resistor R31 are fabricated to be the same as the second resistor R12 and the fourth resistor R14, respectively, the offset voltage Voff can become 0.

This method is advantageous in that the offset generated between the areas and elements can be minimized, compared with the related art employing an orthogonal modulation scheme with one Hall device or the related art canceling an offset by using two or more Hall devices.

Thus, the resistors (including surface resistors) included in the main plate are shared and a single Hall device can deal with the role of two Hall devices by switching the resistors included in the auxiliary plate, and in addition, the deviation of offsets between elements in the related art using two Hall devices can be significantly reduced.

In particular, the present invention requires an additional resistor compared with the related art in which an offset is canceled by using a single Hall device orthogonally, but the present invention is quite advantageous in terms of the area and power consumption over the related art using a plurality of Hall devices such as two or four Hall devices, as well as having advantages in that the offset of the Hall device, a key component of a Hall sensor, can be canceled.

As set forth above, according to exemplary embodiments of the invention, because an offset is canceled by using an additional resistor plate, an occupied area and power consumption can be reduced.

While the present invention has been shown and described in connection with the exemplary embodiments, it will be apparent to those skilled in the art that modifications and variations can be made without departing from the spirit and scope of the invention as defined by the appended claims.

What is claimed is:

1. A Hall device comprising:
a main plate, formed as a first metal plate, including first and second terminals that can be selectively connected to a power source terminal, third and fourth terminals that can be selectively connected to a ground, fifth and sixth terminals that can be connected to first and third terminals, respectively, a first resistor disposed between the first and second terminals, a second resistor disposed between the fifth and sixth terminals, a third resistor disposed between the third and fourth terminals, and a fourth resistor disposed between the second and fourth terminals, all of which being formed on the first metal plate; and
a first auxiliary plate, formed as a second metal plate adjacent to the first metal plate of the main plate, including first and second auxiliary terminals that can be connected to the first and third terminals, and a fifth resistor disposed between the first and second auxiliary terminals, all of which being formed on the second metal plate.

2. The Hall device of claim 1, wherein the fifth resistor has the same resistance value as that of the second resistor.

3. A Hall device comprising:
a main plate, formed as a first metal plate, including first and second terminals that can be selectively connected to a power source terminal, third and fourth terminals that can be selectively connected to a ground, fifth and sixth terminals that can be connected to first and third terminals, respectively, seventh and eighth terminals that can be connected to the second and fourth terminals, respectively, a first resistor disposed between the first and second terminals, a second resistor disposed between the fifth and sixth terminals, a third resistor disposed between the third and fourth terminals, and a fourth resistor disposed between the seventh and eighth terminals, all of which being formed on the first metal plate;
a first auxiliary plate, formed as a second metal plate adjacent to the first metal plate of the main plate, including first and second auxiliary terminals that can be connected to the first and third terminals, and a fifth resistor disposed between the first and second auxiliary terminals, all of which being formed on the second metal plate; and
a second auxiliary plate, formed as a third metal plate adjacent to the first metal plate of the main plate, including third and fourth auxiliary terminals that can be connected to the second and fourth terminals, and a sixth resistor disposed between the third and fourth auxiliary terminals, all of which being formed on the third metal plate.

4. The Hall device of claim 3, wherein the fifth resistor has the same resistance value as that of the second resistor, and the sixth resistor has the same resistance value as that of the fourth resistor.

5. A magnetic sensor circuit comprising:
a Hall device comprising a main plate and a first auxiliary plate wherein the main plate, formed as a first metal plate, comprises first and second terminals that can be selectively connected to a power source terminal, third and fourth terminals that can be selectively connected to a ground, fifth and sixth terminals that can be connected to first and third terminals, respectively, a first resistor disposed between the first and second terminals, a second resistor disposed between the fifth and sixth terminals, a third resistor disposed between the third and fourth terminals, and a fourth resistor disposed between the second and fourth terminals, all of which being formed on the first metal plate, and the first auxiliary plate, formed as a second metal plate adjacent to the first metal plate of the main plate, includes first and second auxiliary terminals that can be connected to the first and third terminals, and a fifth resistor disposed between the first and second auxiliary terminals, all of which being formed on the second metal plate;
a switching circuit unit comprising a first switch that connects the first terminal to one of the fifth terminal and the first auxiliary terminal according to a pre-set first terminal switching signal, and a second switch that connects the third terminal to one of the sixth terminal and the second auxiliary terminal according to a pre-set second terminal switching signal; and
a signal processing unit setting an offset voltage according to a first offset voltage between the second and third terminals selected when a pre-set power switching signal is a first clock and a second offset voltage between the first and fourth terminals selected when the power switching signal PSW is a second clock, in order to cancel an offset.

6. The circuit of claim 5, wherein the fifth resistor has the same resistance value as that of the second resistor.

7. The circuit of claim 5, wherein the magnetic sensor circuit further comprising:
a switching controller generating the first and second terminal switching signals according to a pre-set selection and providing the generated first and second terminal switching signals to the first and second switches.

8. The circuit of claim 7, wherein the first switch is synchronized with the second switch according to the first and second switching signals in order to connect the first terminal to the fifth terminal when the third terminal is connected to the sixth terminal, and connect the first terminal to the first auxiliary terminal when the third terminal is connected to the second auxiliary terminal.

9. The circuit of claim 8, wherein, while the first and third terminals are being connected to the fifth and sixth terminals, respectively, by the first and second switches, the power switching signal becomes a first clock, so the signal processing unit receives a first offset voltage between the second and third terminals, and while the first and third terminals are being connected to the first and second auxiliary terminals, respectively, by the first and second switches, the power switching signal becomes a second clock, so the signal processing unit receives a second offset voltage between the first and fourth terminals.

10. A magnetic sensor circuit comprising:
a Hall device comprising a main plate, a first auxiliary plate and a second auxiliary plate, wherein the main plate, formed as a first metal plate, includes first and second terminals that can be selectively connected to a power source terminal, third and fourth terminals that can be selectively connected to a ground, fifth and sixth terminals that can be connected to first and third terminals, respectively, seventh and eighth terminals that can be connected to the second and fourth terminals, respectively, a first resistor disposed between the first and second terminals, a second resistor disposed between the fifth and sixth terminals, a third resistor disposed between the third and fourth terminals, and a fourth resistor disposed between the seventh and eighth terminals, all of which being formed on the first metal plate, the first auxiliary plate, formed as a second metal plate adjacent to the first metal plate of the main plate, includes first and second auxiliary terminals that can be connected to the first and third terminals, and a fifth resistor disposed between the first and second auxiliary terminals, all of which being formed on the second metal plate, and the second auxiliary plate, formed as a third metal plate adjacent to the first metal plate of the main plate, includes third and fourth auxiliary terminals that can be connected to the second and fourth terminals, and a sixth resistor disposed between the third and fourth auxiliary terminals, all of which being formed on the third metal plate;
a switching circuit unit including a first switch that connects the first terminal to one of the fifth terminal and the first auxiliary terminal according to a pre-set first terminal switching signal, a second switch that connects the third terminal to one of the sixth terminal and the second auxiliary terminal according to a pre-set second terminal switching signal, a third switch that connects the second terminal to one of the seventh terminal and the third auxiliary terminal according to a pre-set third terminal switching signal, and a fourth switch that connects the fourth terminal to one of the eighth terminal and the fourth auxiliary terminal according to a pre-set fourth terminal switching signal; and
a signal processing unit setting an offset voltage according to a first offset voltage between the second and third terminals selected when a pre-set power switching signal is a first clock and a second offset voltage between the first and fourth terminals selected when the power switching signal PSW is a second clock, in order to cancel an offset.

11. The circuit of claim 10, wherein the fifth resistor has the same resistance value as that of the second resistor, and the sixth resistor has the same resistance value as that of the fourth resistor.

12. The circuit of claim 10, further comprising:
a switching controller generating the first, second, third, and fourth terminal switching signals according to a pre-set selection and providing the generated first, second, third, and fourth terminal switching signals to the first, second, third, and fourth switches, respectively.

13. The circuit of claim 12, wherein the first switch is synchronized with the second, third and fourth switches according to the first, second, third and fourth switching signals in order to connect the first terminal to the fifth terminal when the third terminal is connected to the sixth terminal, when the second terminal is connected to the seventh terminal, and the fourth terminal is connected to the eighth terminal, and connect the first terminal to the first auxiliary terminal when the third terminal is connected to the second auxiliary terminal, when the second terminal is connected to the third auxiliary terminal, and when the fourth terminal is connected to the fourth auxiliary terminal.

14. The circuit of claim 13, wherein while the first, second, third, and fourth terminals are being connected to the fifth, seventh, sixth, and eighth terminals, respectively, by the first, second, third and fourth switches, the power switching signal becomes a first clock, so the signal processing unit receives a first offset voltage between the second and third terminals, and while the first, second, third, and fourth terminals are being connected to the first, third, second, and fourth auxiliary terminals, respectively, by the first and second switches, the power switching signal becomes a second clock, so the signal processing unit receives a second offset voltage between the first and fourth terminals.
